(19) United States
(12) Patent Application Publication
(10) Pub. No.: US 2011/0108983 A1
(43) Pub. Date: May 12, 2011

(54) Integrated Circuit

(75) Inventors: Leo Lu, Taoyuan County (TW); Kuei-Wu Chu, Taoyuan County (TW); Jimmy Liang, Taoyuan County (TW)

(73) Assignee: MAO BANG ELECTRONIC CO., LTD., Taoyuan County (TW)

(21) Appl. No.: 12/832,765

(22) Filed: Jul. 8, 2010

(30) Foreign Application Priority Data
Nov. 12, 2009 (TW) 098220979

(51) Int. Cl. H01L 23/498

(52) U.S. Cl. 257/738; 257/E23.069

(57) ABSTRACT

An integrated circuit includes a die including contacts formed thereon. A first dielectric layer is formed on the die. The first dielectric layer includes apertures defined therein corresponding to the contacts. A second dielectric layer is formed on the second dielectric layer. The second dielectric layer includes apertures defined therein corresponding to the apertures of the first dielectric layer. Redistribution layers are located in the apertures of the first and second dielectric layers and connected to the contacts. A passivation layer is located on the second dielectric layer and the redistribution layers. The passivation layer includes apertures corresponding to the redistribution layers. A solder ball is located in each of the apertures of the passivation layer and connected to a related one of the redistribution layers.

### BACKGROUND OF INVENTION

1. Field of Invention

The present invention relates to an integrated circuit and, more particularly, to a reliable integrated that is made easily.

2. Related Prior Art

In a conventional process for packaging an integrated circuit, a die is located on a printed circuit board or conductor rail. Contacts of the die are connected to contacts of the printed circuit board or conductor rail by bonding. Finally, the die and the printed circuit board or conductor rail are packaged to form an integrated circuit.

The connection of the contacts of the die to the contacts of the printed circuit board is done by bonding. This manner of connection is flexible. However, with regard to stacking of dies, different layouts must be made on the dies according to different stacking. Therefore, the design of masks is complicated during the production of wafers, the reliability of resultant dies is jeopardized, the management of the production is made difficult, and the cost of the production is rendered high.

The present invention is therefore intended to obviate or at least alleviate the problems encountered in prior art.

### SUMMARY OF INVENTION

It is the primary objective of the present invention to provide a reliable integrated that is made easily.

To achieve the foregoing objective, the integrated circuit includes a die including contacts formed thereon. A first dielectric layer is formed on the die. The first dielectric layer includes apertures defined therein corresponding to the contacts. A second dielectric layer is formed on the second dielectric layer. The second dielectric layer includes apertures defined therein corresponding to the apertures of the first dielectric layer. Redistribution layers are located in the apertures of the first and second dielectric layers and connected to the contacts. A passivation layer is located on the second dielectric layer and the redistribution layers. The passivation layer includes apertures corresponding to the redistribution layers. A solder ball is located in each of the apertures of the passivation layer and connected to a related one of the redistribution layers.

Other objectives, advantages and features of the present invention will be apparent from the following description referring to the attached drawings.

### BRIEF DESCRIPTION OF DRAWINGS

The present invention will be described via detailed illustration of two embodiments referring to the drawings wherein:

FIG. 1 is a cross-sectional view of an integrated circuit according to the first embodiment of the present invention;

FIGS. 2 to 12 are cross-sectional views for showing a process for making the integrated circuit shown in FIG. 1; and

FIG. 13 is a cross-sectional view of an integrated circuit according to the second embodiment of the present invention.

### DETAILED DESCRIPTION OF EMBODIMENTS

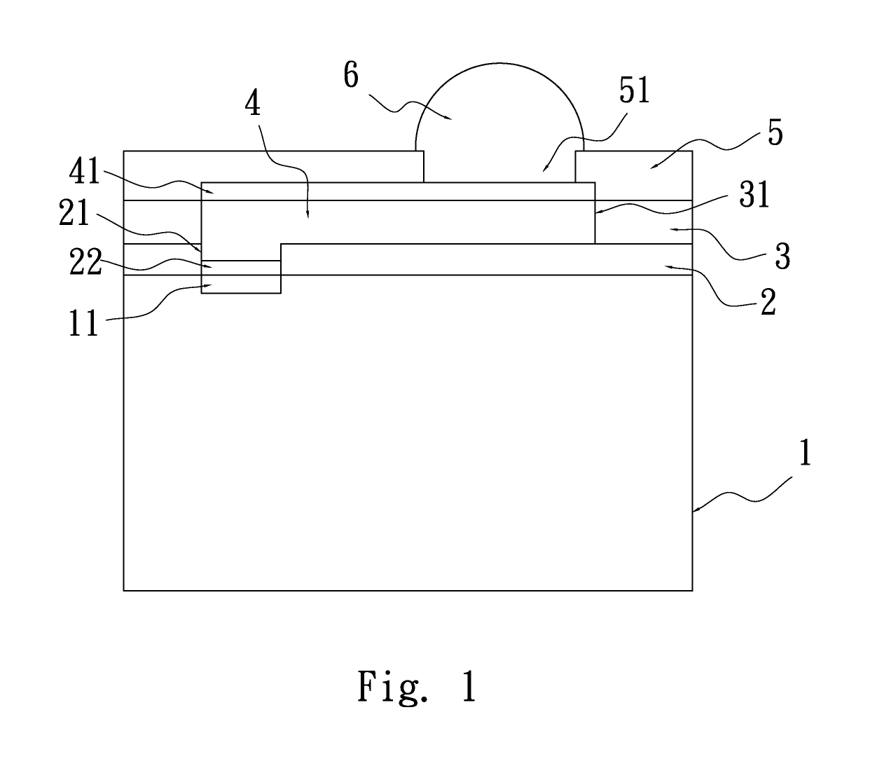

Referring to FIG. 1, an integrated circuit includes a die 1, a first dielectric layer 2, a second dielectric layer 3, redistribution layers 4, a passivation layer 5 and solder balls 6 according to a first embodiment of the present invention. The die 1 includes contacts 11 formed on an upper face for example.

The first dielectric layer 2 is located on the upper face of the die 1. The first dielectric layer 2 includes apertures 21 defined therein corresponding to the contacts 11 formed on the die 1. The first dielectric layer 2 is made of resin or an organic or inorganic isolative material. A connective layer 22 is located in each of the apertures 21. Thus, each of the connective layers 22 is located on an upper face of a related one of the contacts 11.

The second dielectric layer 3 is located on an upper face of the first dielectric layer 2. The second dielectric layer 3 includes apertures 31 defined therein corresponding to the apertures 21. The second dielectric layer 3 is made of resin or an organic or inorganic isolative material.

Each of the redistribution layers 4 is located in a related one of the apertures 31. Thus, each of the redistribution layers 4 is substantially located on the upper face of the first dielectric layer 2. Each of the redistribution layers 4 includes an extensive portion located in a related one of the apertures 21. Thus, the extensive portion of each of the redistribution layers 4 is located on an upper face of a related one of the connective layers 22. The redistribution layer 4 is made of a conductive material. A metal finish 41 is located on an upper face of each of the redistribution layers 4.

The passivation layer 5 is located on an upper face of each of the metal finishes 41 and an upper face of the second dielectric layer 3. The passivation layer 5 includes apertures 51 defined therein corresponding to the metal finishes 41.

Each of the solder balls 6 is located in a related one of the apertures 51. Thus, each of the solder balls 6 is located on the upper face of a related one of the metal finishes 41.

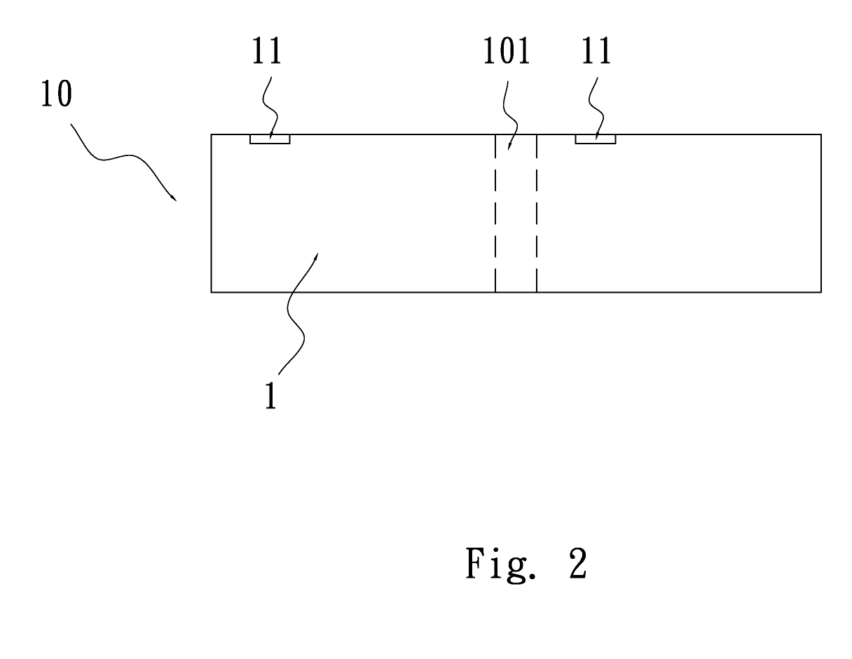

Referring to FIGS. 2 through 12, a process for producing the integrated circuit shown in FIG. 1 will be described. Referring to FIG. 2, the wafer 10 is provided. The 10 can be divided into dies 1 by cuts 101. Each of the dies 1 is made with contacts 11 although only one is shown.

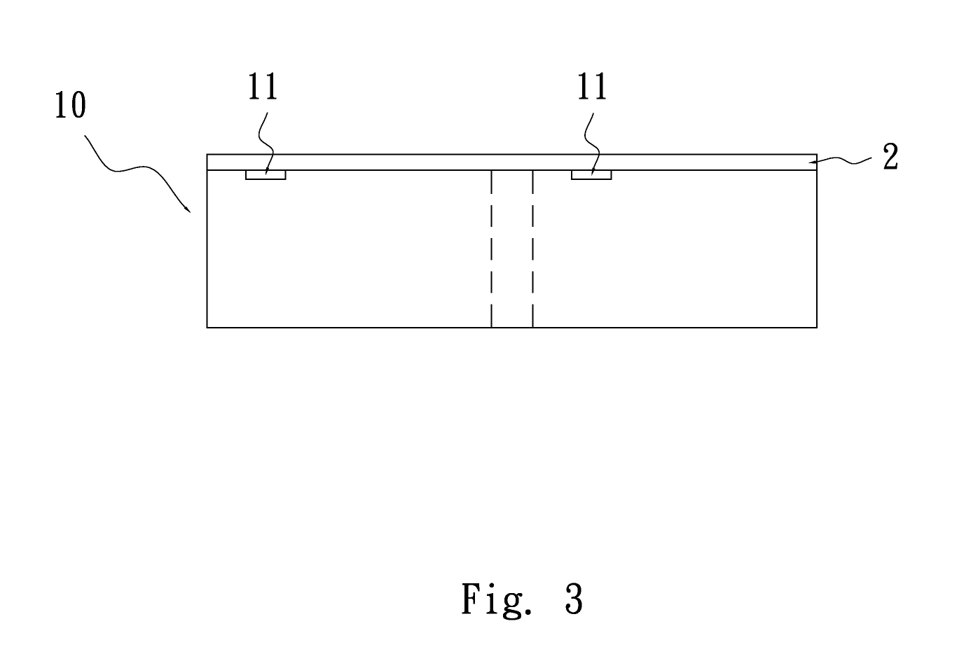

Referring to FIG. 3, the first dielectric layer 2 is made of the resin or the organic or inorganic material on the dies 1 by spin coating, printing, chemical vapor deposition or sputtering for example.

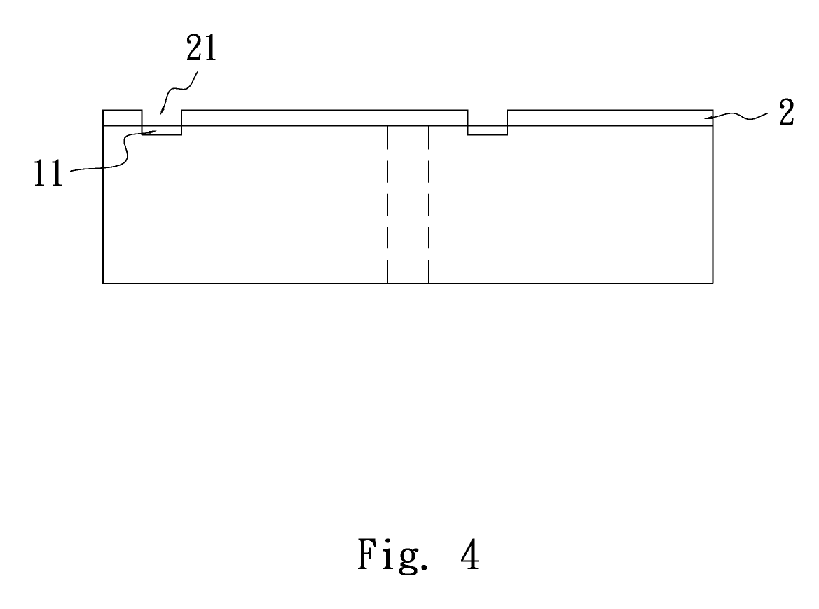

Referring to FIG. 4, corresponding to the contacts 11, the apertures 21 are made in the first dielectric layer 2 by exposure and development, laser or etching for example.

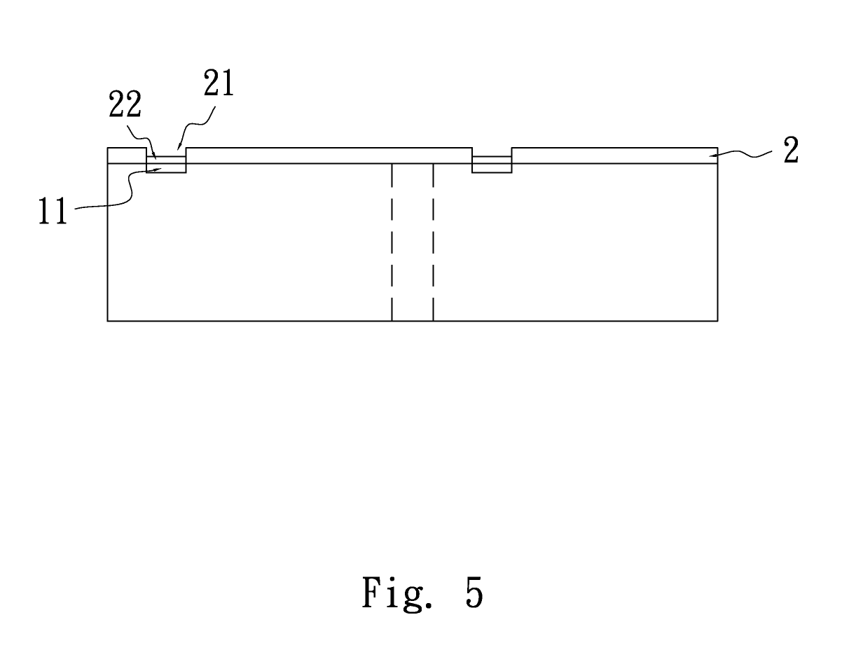

Referring to FIG. 5, each of the connective layers 22 is made of electroless nickel/immersion gold (“ENIG”), immersion silver or immersion tin in the related aperture 21. Each of the connective layers 22 is located on the related contact 11.

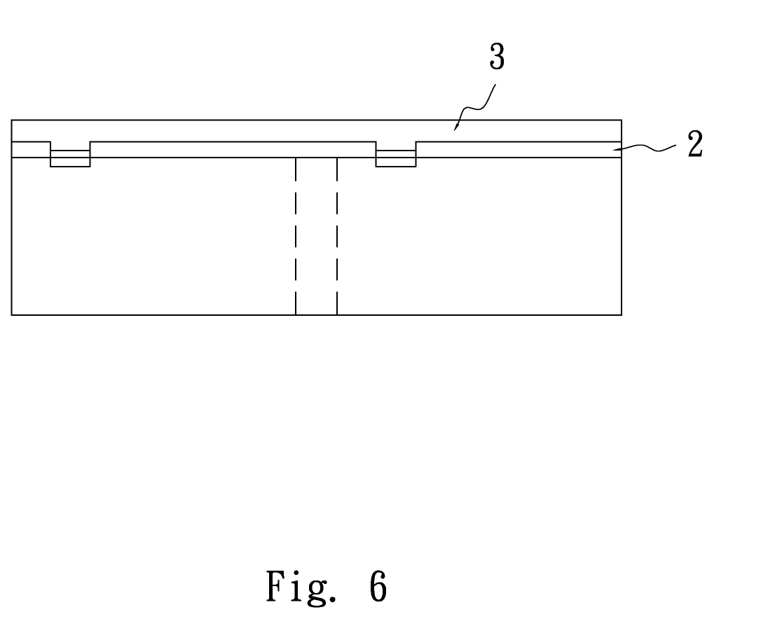

Referring to FIG. 6, the second dielectric layer 3 is made of the resin or the organic or inorganic material on the first dielectric layer 2 by spin coating, printing, chemical vapor deposition or sputtering for example.

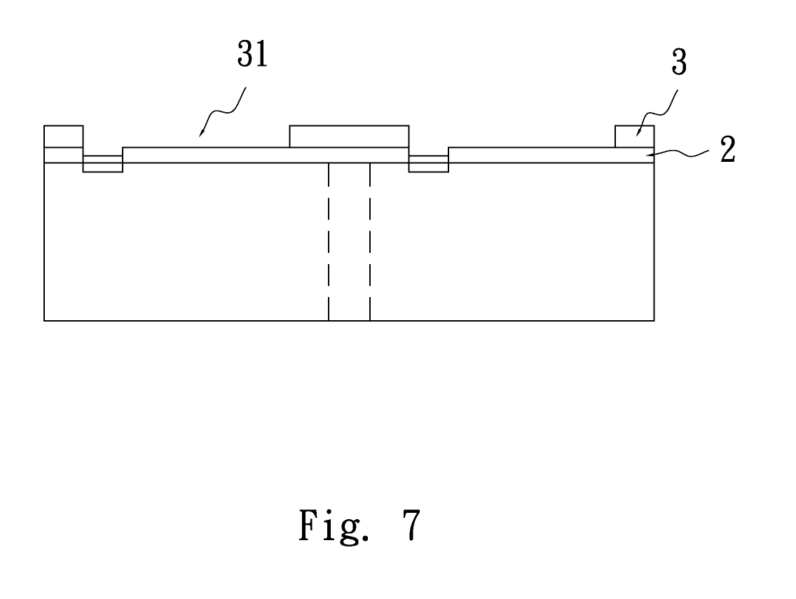

Referring to FIG. 7, corresponding to the apertures 21, the apertures 31 are made in the second dielectric layer 3 by exposure and development, laser or etching for example.

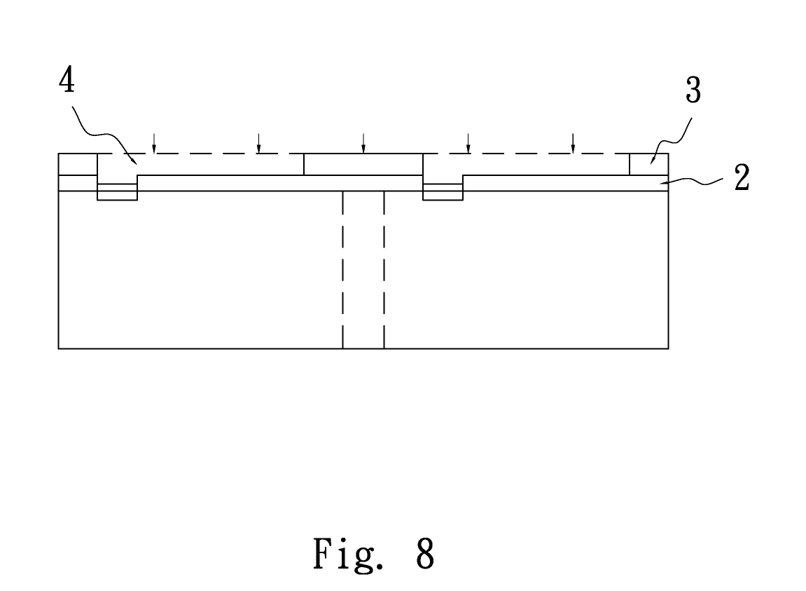

Referring to FIG. 8, each of the redistribution layers 4 is located on the first dielectric layer 2 within the related aperture 31 by printing, coating, spraying, chemical vapor deposition, physical vapor deposition, sputtering, electroplating or any other means. Thus, the extensive portion of each of the redistribution layers 4 is connected to the related connective layer 22 within the related aperture 21. Portions of each of the redistribution layers 4 that extend beyond the upper face of the second dielectric layer 3 are removed by grinding. Thus, the upper face of each of the redistribution layers 4 is in flush with the upper face of second dielectric layer 3.

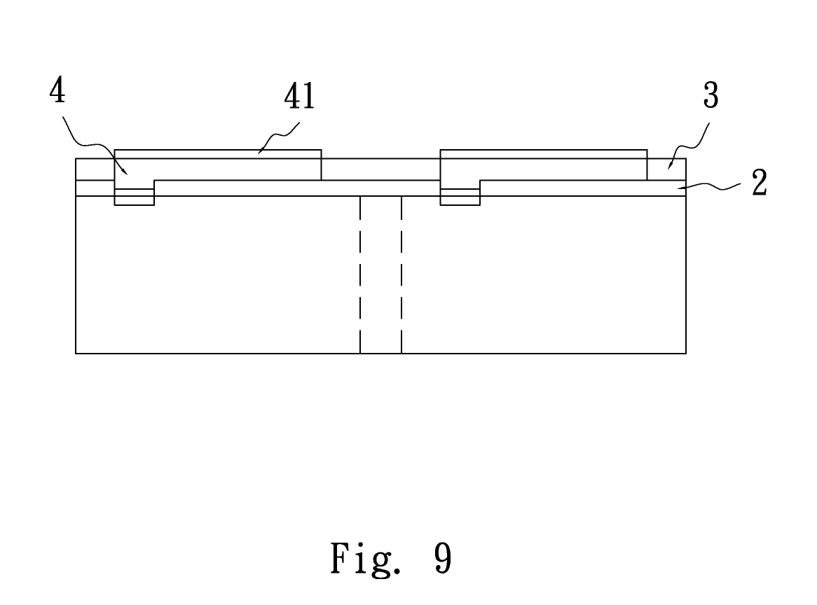

Referring to FIG. 9, each of the metal finishes 41 is located on the related redistribution layer 4 by ENIG, immersion silver or immersion tin for example.

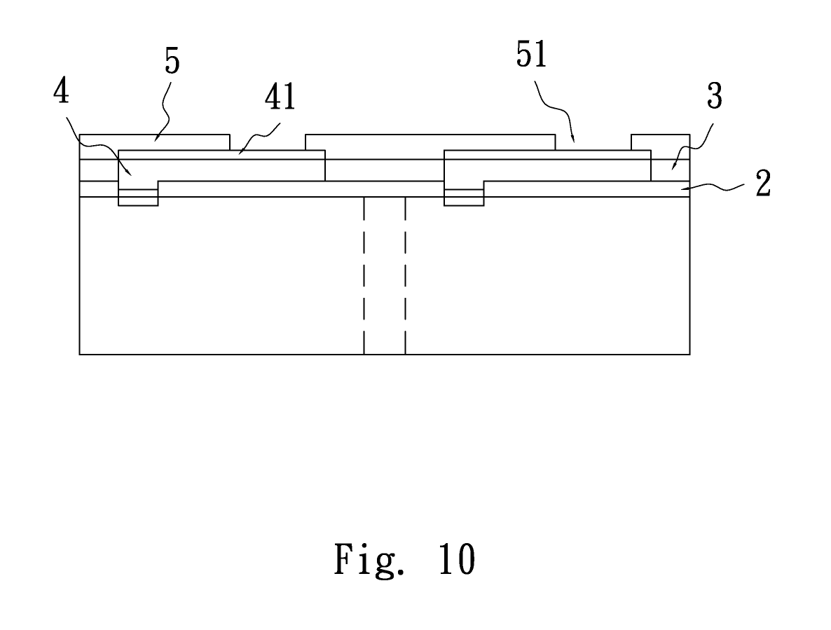

Referring to FIG. 10, the passivation layer 5 is located on the metal finishes 41. Corresponding to the metal finishes 41, the apertures 51 are made in the passivation layer 5.

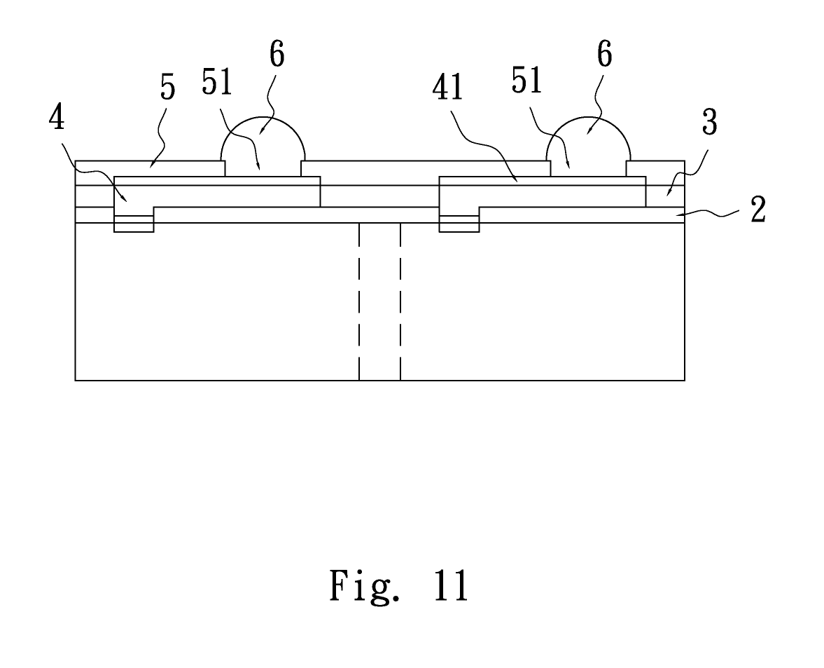

Referring to FIG. 11, each of the solder balls 6 is located in the related aperture 51. Thus, each of the solder balls 6 is connected to the related metal finish 41.

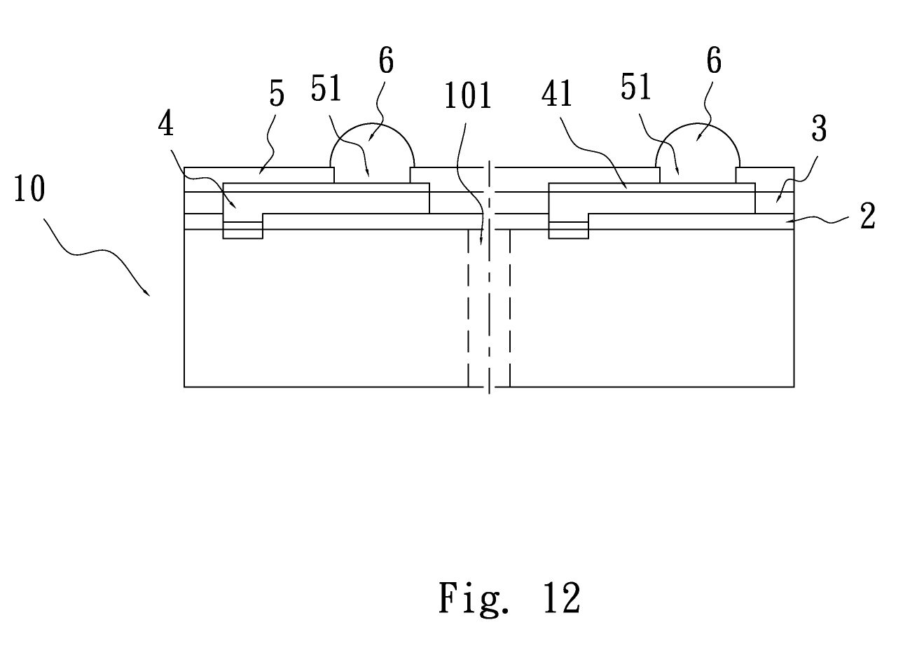

Referring to FIG. 12, the cuts 101 are made in the wafer 10. Thus, the wafer 10 is cut into the dies 1.

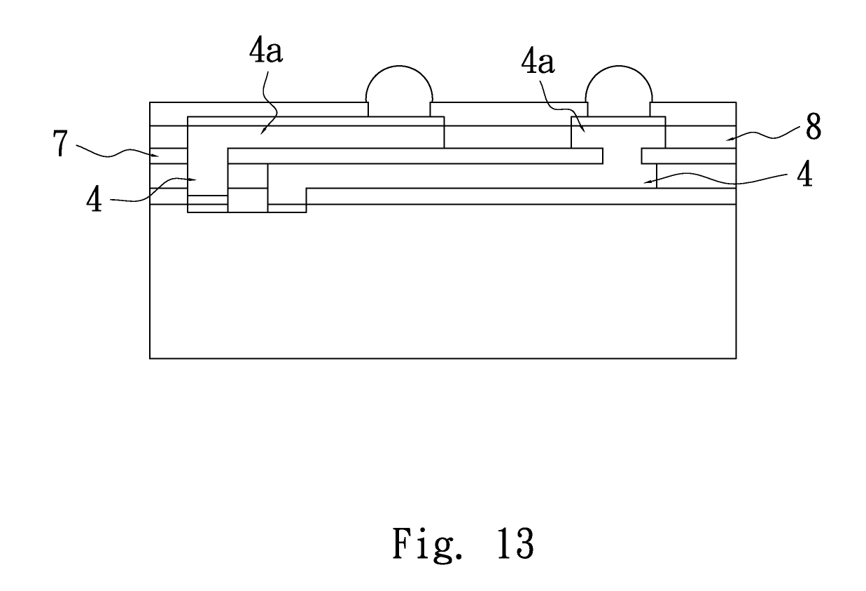

Referring to FIG. 13, there is shown a die according to a second embodiment of the present invention. The second embodiment is like the first embodiment except two things. Firstly, there is a third dielectric layer 7 substantially located on the second dielectric layer 3 and a fourth dielectric layer 8 substantially located on the third dielectric layer 7. Secondly, there are redistribution layers 4a. Each of the redistribution layers 4a is connected to a related one of the redistribution layers 4.

The present invention has been described via the detailed illustration of the embodiments. Those skilled in the art can derive variations from the embodiments without departing from the scope of the present invention. Therefore, the embodiments shall not limit the scope of the present invention defined in the claims.

1. An integrated circuit, comprising:
a die 1 including contacts 11 formed thereon;
a first dielectric layer 2 formed on the die 1, wherein the first dielectric layer 2 includes apertures 21 defined therein corresponding to the contacts 11;
a connective layer 22 located in each of the apertures 21 of the first dielectric layer 2;
a second dielectric layer 3 formed on the second dielectric layer 2, wherein the second dielectric layer 3 includes apertures 31 defined therein corresponding to the apertures 21 of the first dielectric layer 2;
redistribution layers 4 located in the apertures 21, 31 of the first and second dielectric layers 2, 3 and connected to the contacts 11 via the connective layer 22;
a metal finish 41 formed on each of the redistribution layers 4;
a passivation layer 5 located on the second dielectric layer 3 and the redistribution layers 4 and metal finish 41, wherein the passivation layer 5 includes apertures 51 corresponding to the redistribution layers 4; and
solder balls 6 each located in a related one of the apertures 51 of the passivation layer 5 and connected to the metal finish 41.

2. The integrated circuit according to claim 1, wherein the first and second dielectric layers 2, 3 are made of a material selected from the group consisting of resin, an organic isolative material and an inorganic isolative material.

3. The integrated circuit according to claim 1, wherein the first and second dielectric layers 2, 3 are formed according to a technique selected from the group consisting of spin coating, printing, chemical vapor deposition and sputtering.

4. The integrated circuit according to claim 1, wherein the apertures 21, 31 of the first and second dielectric layers 2, 3 are made according to a technique selected from the group consisting of exposure and development, laser and etching.

5. (canceled)

6. The integrated circuit according to claim 1, wherein the connective layers 22 are made of a material selected from the group consisting of electroless nickel/immersion gold, immersion silver, immersion tin.

7. The integrated circuit according to claim 1, wherein the redistribution layers 4 are formed according to a technique selected from the group consisting of printing, coating, spraying, chemical vapor deposition, physical vapor deposition, sputtering, and electroplating.

8. The integrated circuit according to claim 1, wherein the redistribution layers 4 are made of a conductive material.

9. (canceled)

10. The integrated circuit according to claim 1, wherein the metal finishes 41 layers 22 are made of a material selected from the group consisting of electroless nickel/immersion gold, immersion silver, immersion tin.

11. The integrated circuit according to claim 1, wherein the redistribution layers 4 are arranged in two tiers.
